(19) United States
(12) Patent Application Publication
(10) Pub. No.: US 2021/0103835 A1
(43) Pub. Date: Apr. 8, 2021

(54) DATA REDUCTION APPARATUS, DATA REDUCTION METHOD, AND COMPUTER- READABLE RECORDING MEDIUM

(71) Applicant: NEC Corporation, Minato-ku, Tokyo (JP)

(72) Inventor: Itaru HOSOMI, Tokyo (JP)

(73) Assignee: NEC Corporation, Minato-ku, Tokyo (JP)

(21) Appl. No.: 17/044,396

(22) PCT Filed: May 9, 2018
(86) PCT No.: PCT/JP2018/017924

§ 371 Date: Oct. 1, 2020

(51) Int. Cl. G06N 5/04

(52) U.S. Cl. CPC G06N 5/04

(57) ABSTRACT

A data reduction apparatus 10 is an apparatus for reducing a data amount, targeting data having one or more attributes represented by a readable name. The data reduction apparatus 10 includes an attribute classification unit 11 that classifies an attribute of the target data by type based on attribute classification information specifying a subject identification attribute for identifying a subject of an event and a state attribute representing a temporary state or mode of the subject; and an attribute integration unit 12 that, if there are two or more attributes classified as the subject identification attribute as a result of the classification by the attribute classification unit, integrates the two or more attributes classified as the subject identification attribute into one attribute.

### TECHNICAL FIELD

The present invention relates to a data reduction apparatus and a data reduction method for reducing data to be referenced in logical inference, and further relates to a computer-readable recording medium that includes a program recorded thereon for realizing the apparatus and method.

### BACKGROUND ART

Conventionally, technologies have been developed for logically performing inference (hereinafter also referred to as “logical inference”) with a computer by using rules generated in advance or information registered in a dictionary, and data such as observed facts or input queries.

Examples of the applications of such logical inference include data analysis for detecting abnormal data communication. In this case, a large number of communication logs output from a communication device are used as the information.

However, if the data amount of information is too large, an excessive processing load is placed on a program module (hereinafter referred to as “inference engine”) that executes logical inference. Furthermore, since attributes of information such as communication logs tend to increase, the processing load on the inference engine, which specifies the attributes handled in the information in order to identify the information, also increases due to this.

On the other hand, LSI (Latent Semantic Indexing), PLSI (Probabilistic LSI), and LDA (Latent Dirichlet Allocation) are conventionally known as techniques for reducing the data amount. In these techniques, data is represented by vectors, and at this time, each attribute of the data is allocated to each axis in a vector space. Furthermore, in the data (vector) that is provided, multiple axes having similar tendencies of appearance of values are integrated into a single new axis, and accordingly, reduction of data dimensions is realized.

Patent Document 1 also discloses a technique for reducing the data amount. In the technique disclosed in Patent Document 1, if a first logical variable and a second logical variable have a prescribed logical relationship, data amount reduction is achieved by replacing the first logical variable with a logical expression using the second logical variable.

### LIST OF RELATED ART DOCUMENTS

### Patent Document

Patent Document 1: Japanese Patent Laid-Open Publication No. 2016-118867

### SUMMARY OF INVENTION

### PROBLEMS TO BE SOLVED BY THE INVENTION

Incidentally, when the data amount of information used in logical inference is to be reduced, it is required that a subject of an object, a state of the subject, and a behavior of the subject, that are represented by a logical expression of the information, can be identified after the reduction. Furthermore, it is also required that terms that represent the state and the behavior of the subject of the information are represented in a human-readable manner after the reduction.

However, in the above-described LSI, PLSI, and LDA, the axes are integrated based only on the mutual similarity in the meanings or roles, and the axes are not integrated in consideration of what each axis represents for the data. As such, in these techniques, it is impossible to meet the above-described requirements in reduction of the data amount of the information, and thus reduction of the data amount of information used in logical inference is difficult.

Also, in the technique disclosed in Patent Document 1, variables are replaced based only on the equivalence between logical variables in the problem that is presented, and the meanings of the values of the variables are not considered at all. For this reason, in the technique disclosed in Patent Document 1 described above as well, it is impossible to meet the above-described requirements in reduction of the data amount of the information, and thus reduction of the data amount of information used in logical inference is difficult.

An example object of the invention is to provide a data reduction apparatus, a data reduction method, and a computer-readable recording medium that solve the above problems and can achieve data amount reduction of information used in logical inference without impairing the identifiability and readability of a subject and a state and behavior thereof.

### MEANS FOR SOLVING THE PROBLEMS

In order to achieve the above-described example object, a data reduction apparatus according to an example aspect of the invention is an apparatus for reducing an amount of target data including one or more attributes represented by a readable name, the apparatus including:

an attribute classification unit configured to classify an attribute of the target data by type based on attribute classification information specifying a subject identification attribute for identifying a subject of an event and a state attribute representing a temporary state or mode of the subject, and

an attribute integration unit configured to, if there are two or more attributes classified as the subject identification attribute as a result of the classification by the attribute classification unit, integrate the two or more attributes classified as the subject identification attribute into one attribute.

Also, in order to achieve the above-described example object, a data reduction method according to an example aspect of the invention is a method for reducing an amount of target data including one or more attributes represented by a readable name, the method including:

(a) a step of classifying an attribute of the target data by type based on attribute classification information specifying a subject identification attribute for identifying a subject of an event and a state attribute representing a temporary state or mode of the subject; and

(b) a step of integrating, if there are two or more attributes classified as the subject identification attribute as a result of the classification in the (a) step, the two or more attributes classified as the subject identification attribute into one attribute.

Furthermore, in order to achieve the above-described example object, a computer-readable recording medium includes a program recorded thereon for reducing an amount of target data including one or more attributes represented by a readable name, the program including instructions that cause the computer to carry out:

(a) a step of classifying an attribute of the target data by type based on attribute classification information specifying a subject identification attribute for identifying a subject of an event and a state attribute representing a temporary state or mode of the subject; and

(b) a step of integrating, if there are two or more attributes classified as the subject identification attribute as a result of the classification in the (a) step, the two or more attributes classified as the subject identification attribute into one attribute.

### ADVANTAGEOUS EFFECTS OF THE INVENTION

As described above, according to the invention, it is possible to achieve reduction of the data amount of information used in logical inference without impairing the identifiability and readability of a subject and a state and behavior thereof.

### BRIEF DESCRIPTION OF THE DRAWINGS

FIG. 1 is a block diagram showing a schematic configuration of a data reduction apparatus according to an example embodiment of the invention.

FIG. 2 is a block diagram showing a specific configuration of the data reduction apparatus according to the example embodiment of the invention.

FIG. 3 is a flowchart showing operations of the data reduction apparatus according to the example embodiment of the invention.

FIG. 4 is a diagram showing an example of processing results of steps shown in FIG. 3.

FIG. 5 is a diagram illustrating processing of step A4 shown in FIG. 3.

FIG. 6 is a block diagram showing an example of a computer that realizes a data reduction apparatus 10 according to the example embodiment of the invention.

### EXAMPLE EMBODIMENT

### Example Embodiment

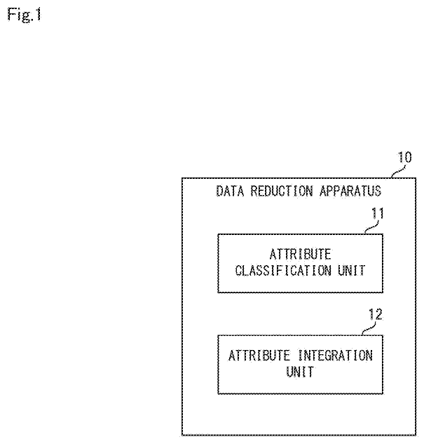

Hereinafter, a data reduction apparatus, a data reduction method, and a program according to an example embodiment of the invention will be described with reference to FIGS. 1 to 6.

[Apparatus Configuration]

First, a schematic configuration of the data reduction apparatus according to the example embodiment will be described with reference to FIG. 1. FIG. 1 is a block diagram showing a schematic configuration of the data reduction apparatus according to the example embodiment of the invention.

A data reduction apparatus 10 according to the example embodiment shown in FIG. 1 is an apparatus for reducing the data amount with respect to data that is referenced in logical inference, specifically, data having one or more attributes represented by readable names. As shown in FIG. 1, the data reduction apparatus 10 is provided with an attribute classification unit 11 and an attribute integration unit 12.

The attribute classification unit 11 classifies attributes of target data by type based on attribute classification information. The attribute classification information is information that specifies a subject identification attribute for identifying a subject of an event and a state attribute that represents a temporal state or mode of the subject.

The attribute integration unit 12 integrates two or more attributes classified as the subject identification attribute into one attribute when there are two or more attributes classified as the subject identification attribute as a result of the classification by the attribute classification unit 11.

In this manner, in the example embodiment, it is possible to integrate two or more attributes classified as the subject identification attribute into one attribute, and reduce the attributes. As such, according to the example embodiment, it is possible to achieve data amount reduction of information used in logical inference without impairing the identifiability and readability of a subject and a state and behavior thereof.

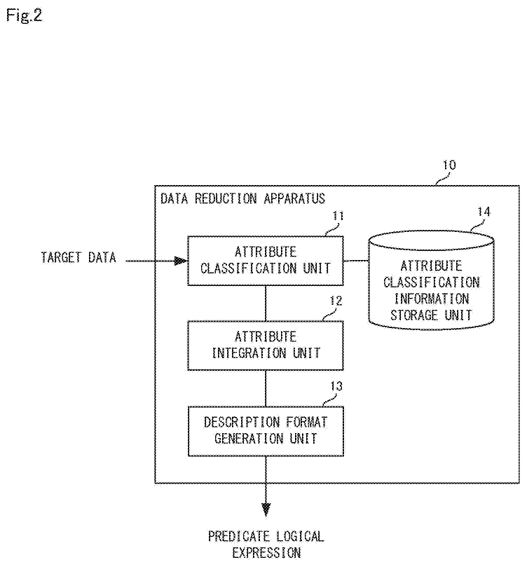

Next, the configuration of the data reduction apparatus 10 according to the example embodiment will be described in more detail with reference to FIG. 2. FIG. 2 is a block diagram showing a specific configuration of the data reduction apparatus according to the example embodiment of the invention.

As shown in FIG. 2, in the example embodiment, the data reduction apparatus 10 is provided with a description format generation unit 13 and an attribute classification information storage unit 14, in addition to the attribute classification unit 11 and the attribute integration unit 12 described above. In the example embodiment, examples of data subjected to data amount reduction include communication logs.

The attribute classification information storage unit 14 stores the attribute classification information. Also, in the example embodiment, the attribute classification information specifies a quantitative attribute that represents a quantity regarding the event, in addition to the subject identification attribute and the state attribute described above. Specifically, the attribute classification information storage unit 14 stores, as the attribute classification information, a table in which the subject identification attribute, the state attribute, and the quantitative attribute are associated with corresponding specific attributes.

For example, when the target data is a communication log, examples of the specific attributes corresponding to the subject identification attribute include filename and transmission-side IP address (hereinafter referred to as “transmission IP”). Examples of specific attributes corresponding to the state attribute include reception-side IP address (hereinafter referred to as “reception IP”), protocol, and communication result. Examples of specific attributes corresponding to the quantitative attribute include date-time, transmission port, reception port, and number of bytes.

In the example embodiment, the attribute classification unit 11 classifies the attributes of the target data as one of the subject identification attribute, the state attribute, and the quantitative attribute with reference to the attribute classification information stored in the attribute classification information storage unit 14.

For example, it is assumed that the target data is a communication log which includes a filename, a transmission IP, a reception IP, a date-time, and a communication result. In this case, the attribute classification unit 11 classifies the filename and the transmission IP as “subject identification attribute”, the reception IP and the communication result as “state attribute”, and the date-time as “quantitative attribute”.

In this case, the attribute integration unit 12 integrates “filename” and “transmission IP” that have been classified as the subject identification attribute into one attribute, and at this time, also integrates the data values included in the attributes. For example, the filename “foo” and the transmission IP “101.11.123.125” are integrated into “foo 101.11.123.125”.

Furthermore, in the example embodiment, when the data values included in the attributes classified as the quantitative attribute satisfy a setting condition, the attribute classification unit 11 re-classifies the attributes that have been classified as the quantitative attribute as the state attribute. Specifically, first, the attribute classification unit 11 performs clustering, or grouping such that the same values are placed in the same group, on the data values included in the attributes classified as the quantitative attribute. In this case, when the number of clusters or groups is much less than the total number of data values (e.g. about one-tenth), the attribute classification unit 11 re-classifies the attributes that have been classified as the quantitative attribute as the state attribute on the setting condition that the number of clusters or groups is much less than the total number of data values.

Furthermore, in the example embodiment, when the attribute classification information specifies the quantitative attribute, the attribute integration unit 12 can delete the attributes having a data value that does not satisfy the setting condition from the attributes that have been classified as the quantitative attributes. For example, if a cluster or a group is not generated through the above-described clustering or grouping, the attribute integration unit 12 deletes the attributes for which a cluster or a group was not generated. This is because such information is meaningless information that does not specify an object, and thus is data unnecessary for logical inference.

The description format generation unit 13 generates a description format of the target data, by using the name given to the target data or the attribute of the target data, after the integration by the attribute integration unit 12. Furthermore, the description format generation unit 13 uses the generated description format to transform the format of the target data into a predicate logical expression.

Specifically, when a name (e.g. “communication log”) is given to the target data, the description format generation unit 13 sets this name as the description format, and generates a predicate logical expression in which the set description format is the predicate. Furthermore, the description format generation unit 13 can also generate a predicate logical expression by using the attributes of the target data to define the upper level of the taxonomy and setting the name of the defined upper level as the description format.

Also, when the number of attributes of the target data exceeds a threshold value after the integration by the attribute integration unit 12, first, the description format generation unit 13 divides the target data into multiple pieces of data such that a setting condition is satisfied. Next, the description format generation unit 13 can also generate the description format for each of the multiple pieces of data (divided data) generated through the division, and generate a predicate logical expression for each pieces of the divided data.

Note that, the setting condition used by the description format generation unit 13 is set based on co-occurrence properties between the data values included in the attributes, for example. Specifically, examples of the setting condition include that the attributes of the data values that correspond to each other are set as one group and the attributes of the data values that do not correspond to each other are set as separate groups.

[Apparatus Operations]

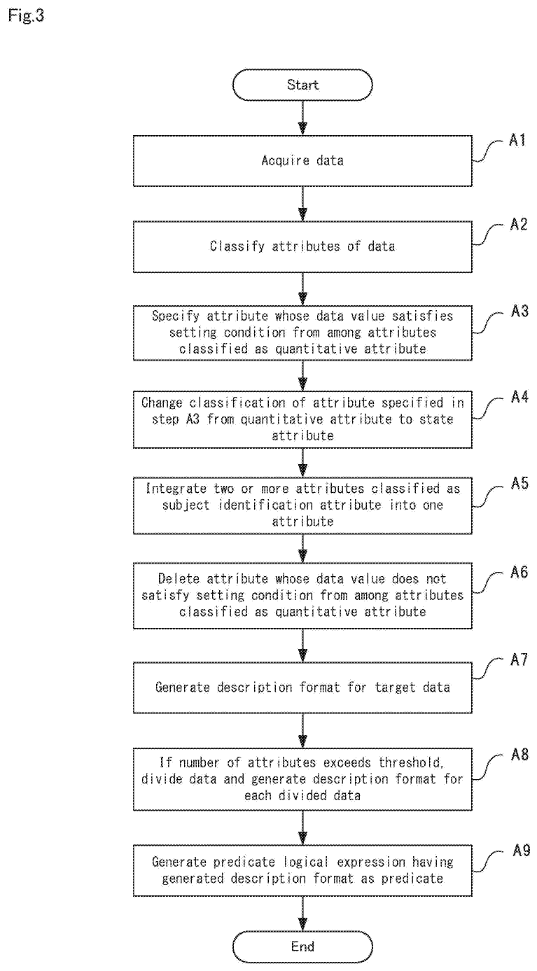

Next, the operations of the data reduction apparatus 10 according to the example embodiment will be described with reference to FIG. 3. FIG. 3 is a flowchart showing the operations of the data reduction apparatus according to the example embodiment of the invention. In the following description, FIGS. 1 and 2 are referred to as appropriate. Also, in the example embodiment, the data reduction method is implemented by operating the data reduction apparatus 10. Accordingly, the following description of the operations of the data reduction apparatus 10 is substituted for a description of the data reduction method according to the example embodiment.

First, as shown in FIG. 3, the data reduction apparatus 10 acquires the target data (step A1).

Next, the attribute classification unit 11 classifies the attributes of the data acquired in step A1 as one of the subject identification attribute, the state attribute, and the quantitative attribute, with reference to the attribute classification information stored in the attribute classification information storage unit 14 (step A2).

Next, the attribute classification unit 11 specifies the attributes having data values that satisfy the setting condition from among the attributes classified as the quantitative attribute (step A3). Examples of the setting condition include that the number of clusters or groups is much less than the total number of data values when clustering or grouping has been performed on the data values included in the attributes classified as the quantitative attribute.

Next, if the attributes have been specified in step A3, the attribute classification unit 11 changes the classification of the specified attributes from the quantitative attribute to the state attribute (step A4).

Next, the attribute integration unit 12 integrates two or more attributes classified as the subject identification attribute into one attribute, on the condition that there are two or more attributes that have been classified as the subject identification attribute as a result of the classification in step A2 (step A5).

Next, the attribute integration unit 12 specifies the attributes including data values that do not satisfy the setting condition from among the attributes that have been classified as the quantitative attribute, and deletes the specified attributes (step A6). Examples of the setting condition in step A6 include that a cluster or a group has been generated through the above-described clustering or grouping.

Next, the description format generation unit 13 uses the name given to the target data or the attribute of the target data to generate a description format for the target data (step A7).

Next, when the number of attributes of the target data after integration exceeds the threshold value, the description format generation unit 13 divides the target data into multiple piece of data such that the number of the state attributes satisfies the setting condition, and generates the description format for each of the divided data generated through the division (step A8).

Next, the description format generation unit 13 generates a predicate logical expression having the generated description format as the predicate (step A9). The predicate logical expression generated in step A9 is inference data used in logical inference.

### SPECIFIC EXAMPLE

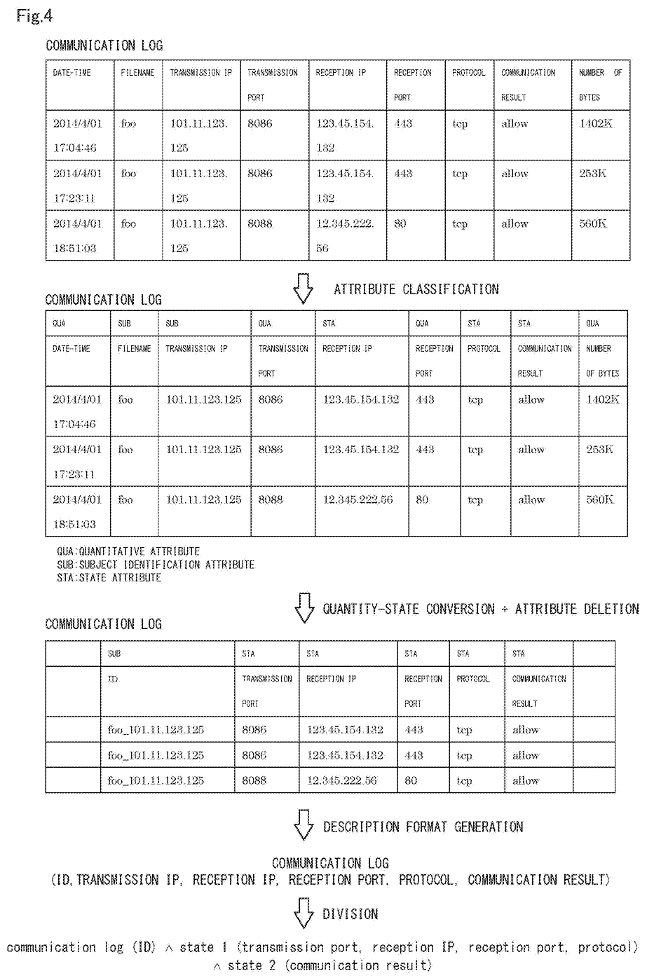

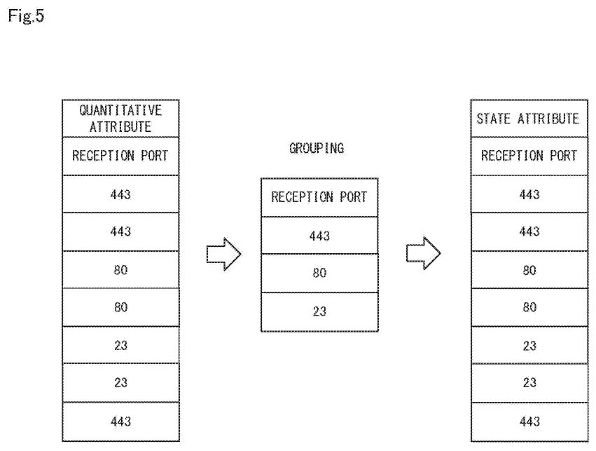

Next, the operations of the data reduction apparatus 10 will be described in more detail with reference to FIGS. 4 and 5. FIG. 4 is a diagram showing an example of processing results of the steps shown in FIG. 3. FIG. 5 is a diagram illustrating processing of step A4 shown in FIG. 3.

In the example shown in FIG. 4, the target data is a communication log. The communication log includes, as the attributes, “date-time”, “filename”, “transmission IP”, “transmission port”, “reception IP”, “reception port”, “protocol”, “communication result”, and “number of bytes”.

Upon performing the processing of step A2 on the data shown in FIG. 4 “filename” and “transmission IP” are classified as the subject identification attribute, “reception IP”, “protocol”, and “communication result” are classified as the state attribute, and “date-time”, “transmission port”, “reception port”, and “number of bytes” are classified as the quantitative attribute.

Upon performing the processing of steps A3 and A4 on the data whose attributes have been classified, as shown in FIG. 5 as well, the classification of “transmission port” and “reception port” is changed from the quantitative attribute to the state attribute. Also, upon performing step A5, “filename” and “transmission IP” that have been classified as the subject identification attribute are integrated. Furthermore, upon performing step A6, “date-time” and “number of bytes” are deleted.

Next, the processing of step A7 is performed on data that has been subjected to processing of steps A3 to A6, the description format is generated with respect to data shown in FIG. 4, and furthermore, when the number of attributes exceeds the threshold value, the data is divided and the predicate logical expression is generated.

Specifically, in the example in FIG. 4, a “communication log (ID, transmission port, reception IP, reception port, protocol, communication result)” is generated. This communication log is divided, and finally, “communication log (ID) A state 1 (transmission port, reception IP, reception port, protocol) A state 2 (communication result)” is generated as a predicate logical expression.

### Effects of Example Embodiment

In the example embodiment described above, two or more attributes classified as the subject identification attribute are integrated into one attribute, and unnecessary attributes among the attributes that have been classified as the quantitative attribute are deleted, and thereafter, a predicate logical expression is generated. For this reason, according to the example embodiment, it is possible to achieve data amount reduction of information used in logical inference while maintaining the identifiability and readability of a subject and a state and (a) behavior thereof

[Program]

A program in the example embodiment of the invention need only be a program that causes a computer to carry out steps Al to A9 shown in FIG. 3. By installing this program to a computer and executing the program, it is possible to realize the data reduction apparatus 10 and the data reduction method in the example embodiment. In this case, the processor of the computer functions as the attribute classification unit 11, the attribute integration unit 12, and the description format generation unit 13, and performs processing. Also, in the example embodiment, the attribute classification information storage unit 14 can be realized by storing a data file constituting the above in a storage device such as hard disk provided in the computer.

Also, the program in the example embodiment may be executed by a computer system that is constituted by a plurality of computers. In this case, for example, each computer may function as any one of the attribute classification unit 11, the attribute integration unit 12, or the description format generation unit 13. Also, the attribute classification information storage unit 14 may be structured on a computer separate from the computer that executes the program according to the example embodiment.

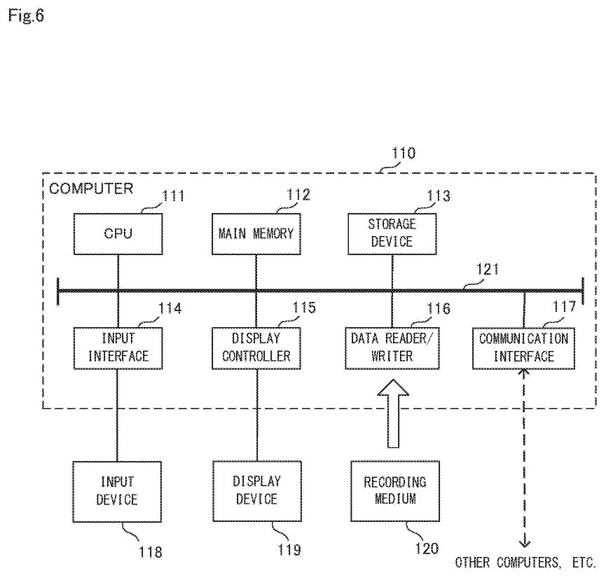

Here, a computer that realizes the data reduction apparatus 10 by executing the program according to the example embodiment will be described with reference to FIG. 6. FIG. 6 is a block diagram showing an example of a computer that realizes the data reduction apparatus 10 according to the example embodiment of the invention.

As shown in FIG. 6, a computer 110 includes a CPU (Central Processing Unit) 111, a main memory 112, a storage device 113, an input interface 114, a display controller 115, a data reader/writer 116, and a communication interface 117. These units are connected so as to be able to communicate with each other via a bus 121. Note that the computer 110 may include a GPU (Graphics Processing Unit) or an FPGA (Field-Programmable Gate Array), in addition to the CPU 111 or instead of the CPU 111.

The CPU 111 performs various computational operations by loading the program (codes) in the example embodiment that are stored in the storage device 113 to the main memory 112, and executing these codes in predetermined order. The main memory 112 typically is a volatile storage device such as a DRAM (Dynamic Random Access Memory). The program in the example embodiment is provided in a state of being stored in a computer-readable recording medium 120. Note that the program in the example embodiment may be distributed over the Internet connected via the communication interface 117.

Specific examples of the storage device 113 include a semiconductor storage device such as a flash memory, in addition to a hard disk drive. The input interface 114 mediates data transmission between the CPU 111 and an input device 118 such as a keyboard or a mouse.

The display controller 115 is connected to a display device 119 and controls display on the display device 119.

The data reader/writer 116 mediates data transmission between the CPU 111 and the recording medium 120, and reads out a program from the recording medium 120 and writes processing results of the computer 110 to the recording medium 120. The communication interface 117 mediates data transmission between the CPU 111 and other computers.

Specific examples of the recording medium 120 include general-purpose semiconductor storage devices such as a USB flash drive, a CF (Compact Flash (registered trademark)) card and an SD (Secure Digital) card, a magnetic recording medium such as a flexible disk, and an optical recording medium such as a CD-ROM (Compact Disk Read Only Memory).

Note that, the data reduction apparatus 10 according to the example embodiment may be realized by using pieces of hardware corresponding to the units rather than a computer on which programs are installed. Furthermore, the data reduction apparatus 10 may be realized by programs in part, and the remaining portion may be realized by hardware.

Note that the example embodiment described above can be partially or wholly realized by supplementary notes 1 to 12 described below, although the invention is not limited to the following description.

(Supplementary Note 1)

A data reduction apparatus for reducing an amount of target data including one or more attributes represented by a readable name, the apparatus including:

an attribute classification unit configured to classify an attribute of the target data by type based on attribute classification information specifying a subject identification attribute for identifying a subject of an event and a state attribute representing a temporary state or mode of the subject; and an attribute integration unit configured to, if there are two or more attributes classified as the subject identification attribute as a result of the classification by the attribute classification unit, integrate the two or more attributes classified as the subject identification attribute into one attribute.

(Supplementary Note 2)

The data reduction apparatus according to supplementary note 1, further including:

a description format generation unit configured to generate a description format with respect to the target data by using a name given to the target data or the attribute of the target data, after the integration by the attribute integration unit.

(Supplementary Note 3)

The data reduction apparatus according to supplementary note 1 or 2,

in which the attribute classification information further specifies a quantitative attribute representing a quantity regarding the event,

the attribute classification unit classifies the attribute of the target data as one of the subject identification attribute, the state attribute, and the quantitative attribute, and if a data value included in the attribute classified as the quantitative attribute satisfies a setting condition, re-classifies the attribute that has been classified as the quantitative attribute as the state attribute, and

the attribute integration unit deletes the attribute including a data value that does not satisfy the setting condition, from among the attributes that have been classified as the quantitative attribute.

(Supplementary Note 4)

The data reduction apparatus according to supplementary note 2,

in which if the number of attributes included in the target data exceeds a threshold value after the integration by the attribute integration unit, the description format generation unit divides the target data into a plurality of pieces of data such that a second setting condition is satisfied, and generates the description format with respect to each of the plurality of pieces of data generated through the division.

(Supplementary Note 5)

A data reduction method for reducing an amount of target data including one or more attributes represented by a readable name, the method including:

(a) a step of classifying an attribute of the target data by type based on attribute classification information specifying a subject identification attribute for identifying a subject of an event and a state attribute representing a temporary state or mode of the subject; and

(b) a step of integrating, if there are two or more attributes classified as the subject identification attribute as a result of the classification in the (a) step, the two or more attributes classified as the subject identification attribute into one attribute.

(Supplementary Note 6)

The data reduction method according to supplementary note 5, further including:

(c) a step of generating a description format with respect to the target data by using a name given to the target data or the attribute of the target data, after the integration in the (b) step.

(Supplementary Note 7)

The data reduction method according to supplementary note 5 or 6, in which the attribute classification information further specifies a quantitative attribute representing a quantity regarding the event,

in the (a) step, the attribute of the target data is classified as one of the subject identification attribute, the state attribute, and the quantitative attribute, and if a data value included in the attribute classified as the quantitative attribute satisfies the setting condition, the attribute that has been classified as the quantitative attribute is re-classified as the state attribute, and

in the (b) step, the attribute including a data value that does not satisfy the setting condition is deleted, from among the attributes that have been classified as the quantitative attribute.

(Supplementary Note 8)

The data reduction method according to supplementary note 6, in which, in the (c) step, if the number of attributes included in the target data exceeds a threshold value after the integration in the (b) step, the target data is divided into a plurality of pieces of data such that a second setting condition is satisfied, and the description format is generated with respect to each of the plurality of pieces of data generated through the division.

(Supplementary Note 9)

A computer-readable recording medium that includes a program recorded thereon for reducing an amount of target data including one or more attributes represented by a readable name, the program including instructions that cause a computer to carry out:

(a) a step of classifying an attribute of the target data by type based on attribute classification information specifying a subject identification attribute for identifying a subject of an event and a state attribute representing a temporary state or mode of the subject; and

(b) a step of integrating, if there are two or more attributes classified as the subject identification attribute as a result of the classification in the (a) step, the two or more attributes classified as the subject identification attribute into one attribute.

(Supplementary Note 10)

The computer-readable recording medium according to supplementary note 9, further including:

(c) a description format generation unit configured to generate a description format with respect to the target data by using a name given to the target data or the attribute of the target data, after the integration in the (b) step.

(Supplementary Note 11)

The computer-readable recording medium according to supplementary note 9 or 10,

in which the attribute classification information further specifies a quantitative attribute representing a quantity regarding the event,

in the (a) step, the attribute of the target data is classified as one of the subject identification attribute, the state attribute, and the quantitative attribute, and if a data value included in the attribute classified as the quantitative attribute satisfies a setting condition, the attribute that has been classified as the quantitative attribute is re-classified as the state attribute, and

in the (b) step, the attribute including a data value that does not satisfy the setting condition is deleted, from among the attributes that have been classified as the quantitative attribute.

(Supplementary Note 12)

The computer-readable recording medium according to supplementary note 10, in which, in the (c) step, if the number of attributes included in the target data exceeds a threshold value after the integration in the (b) step, the target data is divided into a plurality of pieces of data such that a second setting condition is satisfied, and the description format is generated with respect to each of the plurality of pieces of data generated through the division.

Although the invention has been described above with reference to the embodiments, the invention is not limited to the above-described embodiments. Various modifications that can be understood by a person skilled in the art may be made to the configuration and the details of the invention within the scope of the invention.

### INDUSTRIAL APPLICABILITY

As described above, according to the invention, it is possible to achieve data amount reduction of information used in logical inference while maintaining the identifiability and readability of a subject and a state and behavior thereof. The invention is applicable to various systems in which logical inference is performed.

### LIST OF REFERENCE SIGNS

10 Data reduction apparatus

11 Attribute classification unit

12 Attribute integration unit

13 Description format generation unit

14 Attribute classification information storage unit

110 Computer

111 CPU

112 Main memory

113 Storage device

114 Input interface

115 Display controller

116 Data reader/writer

117 Communication interface

118 Input device

119 Display device

120 Storage medium

121 Bus

What is claimed is:

1. A data reduction apparatus for reducing an amount of target data including one or more attributes represented by a readable name, the apparatus comprising:
an attribute classification unit configured to classify an attribute of the target data by type based on attribute classification information specifying a subject identification attribute for identifying a subject of an event and a state attribute representing a temporary state or mode of the subject; and
an attribute integration unit configured to, if there are two or more attributes classified as the subject identification attribute as a result of the classification by the attribute classification unit, integrate the two or more attributes classified as the subject identification attribute into one attribute.

2. The data reduction apparatus according to claim 1, further comprising:
a description format generation unit configured to generate a description format with respect to the target data by using a name given to the target data or the attribute of the target data, after the integration by the attribute integration unit.

3. The data reduction apparatus according to claim 1,
wherein the attribute classification information further specifies a quantitative attribute representing a quantity regarding the event,
the attribute classification unit classifies the attribute of the target data as one of the subject identification attribute, the state attribute, and the quantitative attribute, and if a data value included in the attribute classified as the quantitative attribute satisfies a setting condition, re-classifies the attribute that has been classified as the quantitative attribute as the state attribute, and
the attribute integration unit deletes the attribute including a data value that does not satisfy the setting condition, from among the attributes that have been classified as the quantitative attribute.

4. The data reduction apparatus according to claim 2,
wherein if the number of attributes included in the target data exceeds a threshold value after the integration by the attribute integration unit, the description format generation unit divides the target data into a plurality of pieces of data such that a second setting condition is satisfied, and generates the description format with respect to each of the plurality of pieces of data generated through the division.

5. A data reduction method for reducing an amount of target data including one or more attributes represented by a readable name, the method comprising:
classifying an attribute of the target data by type based on attribute classification information specifying a subject identification attribute for identifying a subject of an event and a state attribute representing a temporary state or mode of the subject; and
integrating, if there are two or more attributes classified as the subject identification attribute as a result of the classification in the, classifying, the two or more attributes classified as the subject identification attribute into one attribute.

6. The data reduction method according to claim 5, further comprising:
generating a description format with respect to the target data by using a name given to the target data or the attribute of the target data, after the integration in the integrating.

7. The data reduction method according to claim 5,
wherein the attribute classification information further specifies a quantitative attribute representing a quantity regarding the event,
in the classifying, the attribute of the target data is classified as one of the subject identification attribute, the state attribute, and the quantitative attribute, and if a data value included in the attribute classified as the quantitative attribute satisfies the setting condition, the attribute that has been classified as the quantitative attribute is re-classified as the state attribute, and
in the integrating, the attribute including a data value that does not satisfy the setting condition is deleted, from among the attributes that have been classified as the quantitative attribute.

8. The data reduction method according to claim 6,
wherein, in the generating, if the number of attributes included in the target data exceeds a threshold value after the integration in the integrating, the target data is divided into a plurality of pieces of data such that a second setting condition is satisfied, and the description format is generated with respect to each of the plurality of pieces of data generated through the division.

9. A non-transitory computer-readable recording medium that includes a program recorded thereon for reducing an amount of target data including one or more attributes represented by a readable name, the program including instructions that cause a computer to carry out:
classifying an attribute of the target data by type based on attribute classification information specifying a subject identification attribute for identifying a subject of an event and a state attribute representing a temporary state or mode of the subject; and
integrating, if there are two or more attributes classified as the subject identification attribute as a result of the classification in the, classifying, the two or more attributes classified as the subject identification attribute into one attribute.

10. The non-transitory computer-readable recording medium according to claim 9, the program further including instructions that cause a computer to carry out:
generating a description format with respect to the target data by using a name given to the target data or the attribute of the target data, after the integration in the integrating.

11. The non-transitory computer-readable recording medium according to claim 9,
wherein the attribute classification information further specifies a quantitative attribute representing a quantity regarding the event,
in the classifying, the attribute of the target data is classified as one of the subject identification attribute, the state attribute, and the quantitative attribute, and if a data value included in the attribute classified as the quantitative attribute satisfies a setting condition, the attribute that has been classified as the quantitative attribute is re-classified as the state attribute, and
in the integrating, the attribute including a data value that does not satisfy the setting condition is deleted, from among the attributes that have been classified as the quantitative attribute.

12. The non-transitory computer-readable recording medium according to claim 10,
wherein, in the generating, if the number of attributes included in the target data exceeds a threshold value after the integration in the integrating, the target data is divided into a plurality of pieces of data such that a second setting condition is satisfied, and the description format is generated with respect to each of the plurality of pieces of data generated through the division.
